(19) United States
(12) Patent Application Publication
(10) Pub. No.: US 2026/0123180 A1
(43) Pub. Date: Apr. 30, 2026

(54) DISPLAY DEVICE INCLUDING CIRCUIT PART AND EMISSION PART

(71) Applicant: LG Display Co., Ltd., Seoul (KR)

(72) Inventors: Hyun-Jik BAE, Gyeonggi-do (KR); Jung-Seop YOON, Gyeonggi-do (KR); Byung-June MUN, Gyeonggi-do (KR)

(21) Appl. No.: 19/284,462

(22) Filed: Jul. 29, 2025

(30) Foreign Application Priority Data
Oct. 30, 2024 (KR) 10-2024-0150377

(51) Int. Cl. H10K 59/121; G09G 3/3225

(52) U.S. Cl. CPC H10K 59/1213; G09G 3/3225

(57) ABSTRACT

A display device including a circuit part and an emission part. The display device includes: a display panel having a display area and a non-display area around the display area; first and second gate driving units in edge portions of the display area; a plurality of circuit parts in a central portion of the display area between the edge portions and connected to the first and second gate driving units; and a plurality of emission parts above the first and second gate driving units and the plurality of circuit parts and connected to the plurality of circuit parts.

### CROSS-REFERENCE TO RELATED APPLICATION

Pursuant to 35 U.S.C. § 119 (a), this present application claims the benefit of an earlier filing date and right of priority to Republic of Korea Patent Application No. 10-2024-0150377 filed on Oct. 30, 2024, the contents of which are hereby incorporated by reference in their entirety.

### TECHNICAL FIELD

The present disclosure relates to a display device.

### BACKGROUND

Recently, various flat panel display devices such as liquid crystal display (LCD) devices, organic light emitting diode (OLED) display devices and field emission display (FED) devices having excellent properties, such as being thin and light-weight with low power consumption, have been developed and applied in various fields.

### SUMMARY

A display device according to some implementations of the present specification includes: a display panel having a display area and a non-display area around the display area; first and second gate driving units in edge portions of the display area; a plurality of circuit parts in a central portion of the display area between the edge portions and connected to the first and second gate driving units; and a plurality of emission parts above the first and second gate driving units and the plurality of circuit parts and connected to the plurality of circuit parts.

It is to be understood that both the foregoing general description and the following detailed description are explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of this specification, illustrate implementations of the disclosure and together with the description serve to explain the principles of the disclosure.

FIG. 1 is a view showing a display device according to an implementation of the present disclosure.

FIG. 2 is a view showing first to third subpixels of a display device according to an implementation of the present disclosure.

FIG. 3 is a view showing first to third emission parts of a pixel of a display device according to an implementation of the present disclosure.

FIG. 4 is a view showing a horizontal pixel line of a display device according to an implementation of the present disclosure.

FIG. 5 is a cross-sectional view showing a circuit part and an emission part of a display device according to an implementation of the present disclosure.

### DETAILED DESCRIPTION

A display device includes a display panel displaying an image and a driving unit supplying a signal and a power to the display panel, and the driving unit includes a gate driving unit and a data driving unit supplying a gate voltage and a data voltage, respectively, to each pixel of the display panel.

In the display device, the gate driving unit may be disposed in the display panel for reducing a material cost. However, a display area is decreased, and a non-display area is increased due to the gate driving unit in the display panel. As a result, it becomes difficult to achieve a narrow bezel.

Accordingly, the present disclosure provides a display device that substantially solves one or more of the problems due to limitations and disadvantages of the related art.

More specifically, the present disclosure is to provide a display device where an area of a non-display area is reduced, a narrow bezel is achieved and a fabrication process is optimized by disposing the first and second gate driving units in the edge portions of the display area, disposing the first, second and third circuit parts in the central portion of the display area, and disposing the first, second and third emission parts (which may also be referred as the first, second and third light emission parts, respectively) in the central portion and the edge portions of the display area.

Additional features and advantages of the disclosure will be set forth in the description which follows, and in part will be apparent from the description, or may be learned by practice of the disclosure. These and other advantages of the disclosure will be realized and attained by the structure particularly pointed out in the written description and claims hereof as well as the appended drawings.

To achieve these and other advantages and in accordance with the purpose of the present disclosure, as embodied and broadly described herein,

Advantages and features of the present disclosure, and implementation methods thereof will be clarified through following example aspects described with reference to the accompanying drawings. The present disclosure may, however, be embodied in different forms and should not be construed as limited to the example aspects set forth herein. Rather, these example aspects are provided so that this disclosure may be sufficiently thorough and complete to assist those skilled in the art to fully understand the scope of the present disclosure. Further, the present disclosure is only defined by scopes of claims.

The shapes, sizes, ratios, angles, numbers, and the like, which are illustrated in the drawings to describe various example aspects of the present disclosure, are merely given by way of example. Therefore, the present disclosure is not limited to the illustrations in the drawings. Like reference numerals refer to like elements throughout the specification, unless otherwise specified.

In the following description, where the detailed description of the relevant known function or configuration may unnecessarily obscure a feature or aspect of the present disclosure, a detailed description of such known function or configuration may be omitted or a brief description may be provided.

Where the terms “comprise,” “have,” “include,” and the like are used, one or more other elements may be added unless the term, such as “only,” is used. An element described in the singular form is intended to include a plurality of elements, and vice versa, unless the context clearly indicates otherwise.

In construing an element, the element is to be construed as including an error or a tolerance range even where no explicit description of such an error or tolerance range is provided.

Where positional relationships are described, for example, where the positional relationship between two parts is described using “on,” “over,” “under,” “above,” “below,” “beside,” “next,” or the like, one or more other parts may be located between the two parts unless a more limiting term, such as “immediate (ly),” “direct (ly),” or “close (ly)” is used. For example, where an element or layer is disposed “on” another element or layer, a third layer or element may be interposed therebetween.

Although the terms “first,” “second,” A, B, (a), (b), and the like may be used herein to refer to various elements, these elements should not be interpreted to be limited by these terms as they are not used to define a particular order or precedence. These terms are only used to distinguish one element from another. For example, a first element could be termed a second element, and, similarly, a second element could be termed a first element, without departing from the scope of the present disclosure.

The term “at least one” should be understood to include all combinations of one or more of related elements. For example, the term of “at least one of first, second and third elements” may include all combinations of two or more of the first, second and third elements as well as the first, second or third element.

The term “display device” may include a display device in a narrow sense such as liquid crystal module (LCM), an organic light emitting diode (OLED) module and a quantum dot (QD) module including a display panel and a driving unit for driving the display panel. In addition, the term “display device” may include a complete product (or a final product) including the LCM, the OLED module and the QD module such as a notebook computer, a television, a computer monitor, an equipment display device including an automotive display apparatus or a shape other than a vehicle, and a set electronic apparatus or a set device (or a set apparatus) such as a mobile electronic apparatus of a smart phone or an electronic pad.

Accordingly, a display device of the present disclosure may include an applied product or a set device of a final user's device including the LCM, the OLED module and the QD module as well as a display device in a narrow sense such as the LCM, the OLED module and the QD module.

According to circumstances, the LCM, the OLED module and the QD module having a display panel and a driving unit may be expressed as “a display device”, and an electronic apparatus of a complete product including the LCM, the OLED module and the QD module may be expressed as “a set device.” For example, a display device in a narrow sense may include a display panel of a liquid crystal, an organic light emitting diode and a quantum dot and a source printed circuit board (PCB) of a control unit for driving the display panel, and a set device may further include a set PCB of a set control unit electrically connected to the source PCB for controlling the entire set device.

The display panel of the present disclosure may include all kinds of display panels such as a liquid crystal display panel, an organic light emitting diode display panel, a quantum dot display panel and an electroluminescent display panel. The display panel of the present disclosure is not limited to a specific display panel of a bezel bending having a flexible substrate for an organic light emitting diode display panel and a lower back plate supporter. A shape or a size of the display panel for the display device of the present disclosure is not limited thereto.

For example, when the display panel is an organic light emitting diode display panel, the display panel may include a plurality of gate lines, a plurality of data lines and a subpixel in a crossing region of the plurality of gate lines and the plurality of data lines. The display panel may include an array having a thin film transistor of an element for selectively applying a voltage to each subpixel, an emitting element layer on the array and an encapsulating substrate or an encapsulation part covering the emitting element layer. The encapsulation part may protect the thin film transistor and the emitting element layer from an external impact and may prevent or at least reduce penetration of a moisture or oxygen into the emitting element layer. In addition, the emitting element layer on the array may include an inorganic light emitting layer, for example, a nano-sized material layer or a quantum dot.

The thin film transistor of the present disclosure may include one of an oxide thin film transistor, an amorphous silicon thin film transistor, and a low temperature polycrystalline silicon thin film transistor.

Features of various implementations of the present disclosure may be partially or entirely coupled to or combined with each other. They may be linked and operated technically in various ways as those skilled in the art may sufficiently understand. The aspects may be carried out independently of or in association with each other in various combinations.

Hereinafter, a display device according to various example implementations of the present disclosure where an influence on an oxide semiconductor layer of a thin film transistor of a driving element part is reduced by shielding a light emitted and transmitted from a subpixel and/or a light inputted from an exterior will be described in detail with reference to the accompanying drawings.

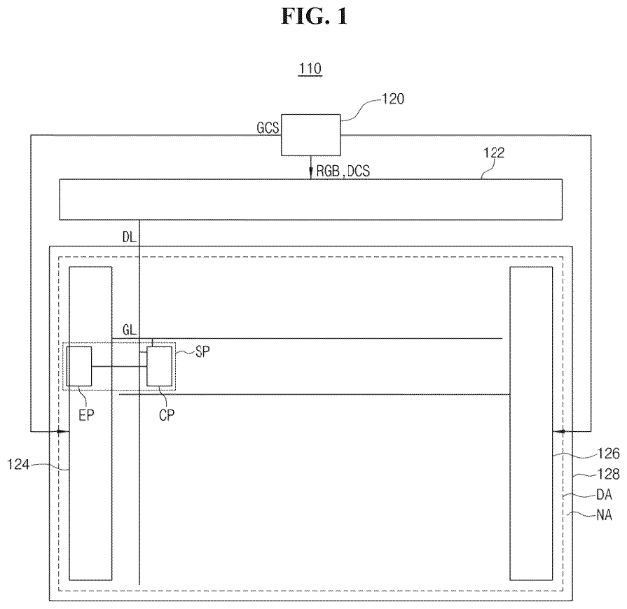

FIG. 1 is a view showing a display device according to an implementation of the present disclosure. Although the display device may be an organic light emitting diode (OLED) display device, it is not limited thereto. For example, the display device may be a quantum dot display device, a micro light emitting diode (LED) display device or a mini light emitting diode (LED) display device.

In FIG. 1, a display device 110 according to an implementation of the present disclosure includes a timing controlling unit 120 (e.g., a circuit), a data driving unit 122 (e.g., a circuit), first and second gate driving units 124 and 126 (e.g., circuits) and a display panel 128.

The timing controlling unit 120 generates an image data RGB, a data control signal DCS and a gate control signal GCS using an image signal and a plurality of timing signals including a data enable signal, a horizontal synchronization signal, a vertical synchronization signal and a clock signal transmitted from an external system such as a graphic card or a television system. The timing controlling unit 120 transmits the image data RGB and the data control signal DCS to the data driving unit 122, and transmits the gate control signal GCS to the first and second gate driving units 124 and 126.

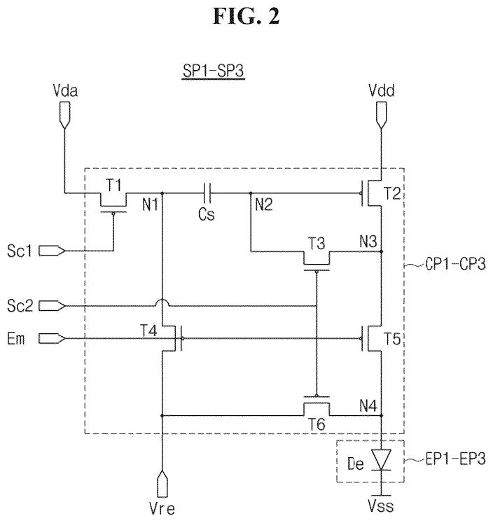

The data driving unit 122 generates a data signal (a data voltage) Vda (of FIG. 2) using the image data RGB and the data control signal DCS transmitted from the timing controlling unit 120 and transmits the data signal Vda to a data line DL of the display panel 128.

The first and second gate driving units 124 and 126 generate a gate signal (a gate voltage) Sc1, Sc2 and an emission signal Em (of FIG. 2) using the gate control signal GCS transmitted from the timing controlling unit 120 and applies the gate signal Sc1, Sc2 and the emission signal Em to a gate line GL of the display panel 128.

The first and second gate driving units 124 and 126 may have a gate in panel (GIP) type to be formed in a display area DA of a substrate of the display panel 128 having the gate line GL, the data line DL and a subpixel SP.

Although the first and second gate driving units 124 and 126 are disposed in both side portions of the display panel 128 in the implementation of FIG. 1, only one gate driving unit may be disposed in one side portion of the display panel 128 in another implementation.

The display panel 128 includes a display area DA at a central portion thereof and a non-display area NA surrounding the display area DA. The display panel 128 displays an image using the gate signal Sc1, Sc2 and the emission signal Em and the data signal Vda. For displaying an image, the display panel 128 includes a plurality of subpixels SP, a plurality of gate lines GL and a plurality of data lines DL in the display area DA.

The plurality of gate lines GL and the plurality of data lines DL cross each other, and each of the plurality of subpixels SP includes a circuit part CP and an emission part EP. The circuit part CP is connected to the gate line GL and the data line DL, and the emission part EP is connected to the circuit part CP.

The circuit part CP includes a plurality of transistors (e.g., first to sixth transistors T1 to T6 of FIG. 2) and at least one capacitor (e.g., a storage capacitor Cs of FIG. 2) to drive the emission part EP. The emission part EP includes at least one emission element (e.g., light emitting diode De of FIG. 2) to emit a light.

The first and second gate driving units 124 and 126 are disposed in left and right edge portions EA (of FIG. 4) of the display area DA. The circuit parts CP of the plurality of subpixels SP are disposed in a central portion CA (of FIG. 4) between the left and right edge portions EA of the display area DA, and the emission parts of the plurality of subpixels SP are disposed throughout an entirety of the display area DA.

As a result, the emission parts EP of the plurality of subpixels SP are not disposed directly above the circuit parts CP connected to the emission parts EP and are shifted along (each of) left and right directions from a region directly above the circuit parts CP connected to the emission parts EP. At least two of the emission parts EP of the plurality of subpixels SP may be disposed above the first and second gate driving units 124 and 126.

For example, the plurality of emission parts EP of a left half portion of one horizontal pixel line including the plurality of subpixels SP arranged in one line along a horizontal direction are arranged by being shifted by different shift values along a left direction from the regions directly above the circuit parts CP connected to the emission parts EP. The plurality of emission parts EP of a right half portion of one horizontal pixel line are arranged by being shifted by different shift values along a right direction from the regions directly above the circuit parts CP connected to the emission parts EP.

The shift values of the plurality of emission parts EP may gradually increase from a central line of one horizontal pixel line to left and right end lines, for example, of the display area (or, the left end and right end of the horizontal pixel line).

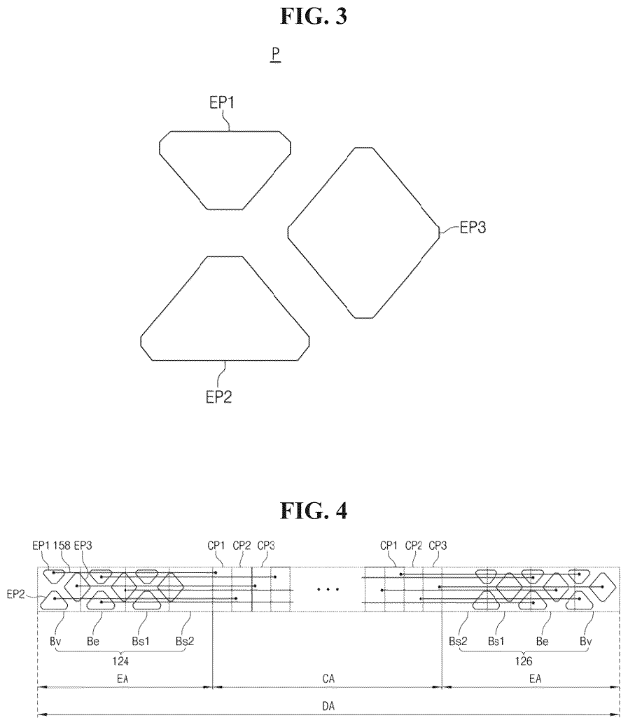

FIG. 2 is a view showing first to third subpixels of a display device according to an implementation of the present disclosure, and FIG. 3 is a view showing first to third emission parts of a pixel of a display device according to an implementation of the present disclosure.

In FIG. 2, the plurality of subpixels SP of the display panel 128 of the display device 110 according to an implementation of the present disclosure include first, second and third subpixels SP1, SP2 and SP3. The first subpixel SP1 includes a first circuit part CP1 and a first emission part EP1, the second subpixel SP2 includes a second circuit part CP2 and a second emission part EP2, and the third subpixel SP3 includes a third circuit part CP3 and a third emission part EP3.

For example, the first, second and third subpixels SP1, SP2 and SP3 may correspond to red, green and blue colors, respectively, and the first, second and third subpixels SP1, SP2 and SP3 may constitute one pixel P (of FIG. 3).

Each of the first, second and third circuit parts CP1, CP2 and CP3 includes first to sixth transistors T1 to T6 and a storage capacitor Cs, and each of the first, second and third emission parts EP1, EP2 and EP3 includes a light emitting diode De.

Although each of the first, second and third circuit parts CP1, CP2 and CP3 has a 6T1C structure having six transistors and one storage capacitor in the implementation of FIG. 2, each of the first, second and third circuit parts CP1, CP2 and CP3 may have one of a 3T1C structure having three transistors and one storage capacitor, a 7T1C structure having seven transistors and one storage capacitor and a 8T1C structure having eight transistors and one storage capacitor in another implementation.

Although the first to sixth transistors T1 to T6 have a positive type (i.e., P type) in the implementation of FIG. 2, at least one of the first to sixth transistors T1 to T6 may have a negative type (i.e., N type) in another implementation.

The first transistor T1 is switched according to a scan1 signal Sc1 to transmit a data signal Vda to a first node N1.

A gate electrode of the first transistor T1 is connected to the gate line GL to receive the scan1 signal Sc1, a source electrode of the first transistor T1 is connected to the data line DL to receive the data signal Vda, and a drain electrode of the first transistor T1 is connected to the first node N1.

The second transistor T2 is switched according to a voltage of a second node N2 to transmit a high level signal (high level voltage) Vdd to a third node N3.

A gate electrode of the second transistor T2 is connected to the second node N2, a source electrode of the second transistor T2 is connected to a high level power line to receive the high level signal Vdd, and a drain electrode of the second transistor T2 is connected to the third node N3.

The third transistor T3 is switched according to a scan2 signal Sc2 to transmit a voltage of the third node N3 to the second node N2.

A gate electrode of the third transistor T3 is connected to the gate line GL to receive the scan2 signal Sc2, a source electrode of the third transistor T3 is connected to the third node N3, and a drain electrode of the third transistor T3 is connected to the second node N2.

The fourth transistor T4 is switched according to an emission signal Em to transmit a reference signal Vre to the first node N1.

A gate electrode of the fourth transistor T4 is connected to the gate line GL to receive the emission signal Em, a source electrode of the fourth transistor T4 is connected to the first node N1, and a drain electrode of the fourth transistor T4 is connected to a reference line to receive the reference signal Vre.

The fifth transistor T5 is switched according to the emission signal Em to transmit a voltage of the third node N3 to a fourth node N4.

A gate electrode of the fifth transistor T5 is connected to the gate line GL to receive the emission signal Em, a source electrode of the fifth transistor T5 is connected to the third node N3, and a drain electrode of the fifth transistor T5 is connected to the fourth node N4.

The sixth transistor T6 is switched according to the scan2 signal Sc2 to transmit the reference signal Vre to the fourth node N4.

A gate electrode of the sixth transistor T6 is connected to the gate line GL to receive the scan2 signal Sc2, a source electrode of the sixth transistor T6 is connected to the fourth node N4, and a drain electrode of the sixth transistor T6 is connected to the reference line to receive the reference signal Vre.

The storage capacitor Cs keeps the data signal Vdata supplied to the first node N1 for one frame and stores a threshold voltage Vth of the second transistor T2 which is a driving transistor.

The drain electrode of the first transistor T1, the source electrode of the fourth transistor T4 and a first capacitor electrode of the storage capacitor Cs constitute the first node N1, and a second capacitor electrode of the storage capacitor Cs, the gate electrode of the second transistor T2 and the drain electrode of the third transistor T3 constitute the second node N2. The drain electrode of the second transistor T2, the source electrode of the third transistor T3 and the source electrode of the fifth transistor T5 constitute the third node N3, and the drain electrode of the fifth transistor T5 and the source electrode of the sixth transistor T6 constitute the fourth node N4.

The light emitting diode De emits a light of a luminance proportional to a current of the second transistor T2 which is a driving transistor.

An anode of the light emitting diode De is connected to the fourth node N4, and a cathode of the light emitting diode De is connected to a low level power line to receive a low level signal (low level voltage) Vss.

The first, second and third emission parts EP1, EP2 and EP3 may display an image having a luminance corresponding to the image data RGB according to driving of the first, second and third circuit parts CP1, CP2 and CP3 of the first, second and third subpixels SP1, SP2 and SP3.

In FIG. 3, one pixel P of the display panel 128 of the display device 110 according to an implementation of the present disclosure includes the first, second and third subpixels SP1, SP2 and SP3, and the first, second and third subpixels SP1, SP2 and SP3 include the first, second and third emission parts EP1, EP2 and EP3, respectively.

The first emission part EP1 may have a chamfered inverted triangle shape, the second emission part EP2 may have a chamfered triangle shape, and the third emission part EP3 may have a chamfered lozenge shape. The first, second and third emission parts EP1, EP2 and EP3 may correspond to red, green and blue colors, respectively.

The first and second emission parts EP1 and EP2 may be arranged in one line along a vertical direction, and the third emission part EP3 may be arranged at a right portion of the first and second emission parts EP1 and EP2 along a horizontal direction.

An area of the second emission part EP2 may be greater than an area of the first emission part EP1 and may be smaller than an area of the third emission part EP3.

In another implementation, one pixel P may include first, second, third and fourth subpixels corresponding to red, green, blue and white colors, respectively, or first, second and third subpixels SP1, SP2 and SP3 may be arranged in one line along a horizontal direction.

One horizontal pixel line of the display device will be illustrated with reference to a drawing.

FIG. 4 is a view showing a horizontal pixel line of a display device according to an implementation of the present disclosure.

In FIG. 4, the first and second gate driving units 124 and 126 are disposed as a lower layer of the left and right edge portions EA of the display area DA of the display device 110 according to an implementation of the present disclosure. The first, second and third circuit parts CP1, CP2 and CP3 of the plurality of subpixels SP are sequentially and repeatedly disposed as a lower layer of the central portion CA between the left and right edge portions EA of the display area DA. The first, second and third emission parts EP1, EP2 and EP3 of the plurality of subpixels SP are sequentially and repeatedly disposed as an upper layer of the entire display area DA.

For example, a low level block Bv, an emission block Be, a scan1 block Bs1 and a scan2 block Bs2 may be sequentially disposed from the edge portion EA to the central portion CA as a lower layer of the left and right edge portions EA of one horizontal pixel line constituted by the plurality of subpixels SP of the display area DA arranged in one line along a horizontal direction.

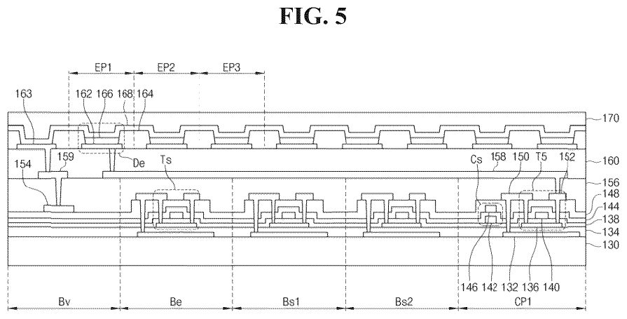

The low level block Bv may include a low level power line transmitting the low level signal Vss. Each of the emission block Be, the scan1 block Bs1 and the scan2 block Bs2 may include a plurality of stage transistors Ts (of FIG. 5) constituting a stage of a shift register generating the emission signal Em, the scan1 signal Sc1 and the scan2 signal Sc2.

In another implementation, the structure and the arrangement order of the plurality of blocks of the first and second gate driving units 124 and 126 may be variously changed.

The first, second and third circuit parts CP1, CP2 and CP3 are sequentially and repeatedly disposed from a left portion to a right portion as a lower layer of the central portion CA of one horizontal pixel line of the display area DA.

The low level block Bv, the emission block Be, the scan1 block Bs1 and the scan2 block Bs2 of the first and second gate driving units 124 and 126 of the edge portions EA of the display area DA are connected to each of the first, second and third circuit parts CP1, CP2 and CP3 of the central portion CA of the display area DA to supply the low level signal Vss, the emission signal Em, the scan1 signal Sc1 and the scan2 signal Sc2.

The first, second and third emission parts EP1, EP2 and EP3 are sequentially and repeatedly disposed as an upper layer of the central portion CA and the edge portions EA of one horizontal pixel line of the display area DA.

The first, second and third circuit parts CP1, CP2 and CP3 of the central portion CA of the display area DA are connected to the first, second and third emission parts EP1, EP2 and EP3, respectively, of the central portion CA and the edge portions EA of the display area DA through a connecting electrode 158 to supply a current corresponding to the data signal Vda.

As a result, the first, second and third emission parts EP1, EP2 and EP3 are disposed above the first and second gate driving units 124 and 126 in the edge portions EA of one horizontal pixel line of the display area DA, and the first, second and third emission parts EP1, EP2 and EP3 are disposed above the first, second and third circuit parts CP1, CP2 and CP3 in the central portion CA of one horizontal pixel line of the display area DA.

The first, second and third emission parts EP1, EP2 and EP3 are not disposed directly above the first, second and third circuit parts CP1, CP2 and CP3 connected to the first, second and third emission parts EP1, EP2 and EP3 and are shifted along left and right directions from a region directly above the first, second and third circuit parts CP1, CP2 and CP3 connected to the first, second and third emission parts EP1, EP2 and EP3. At least one of the plurality of first emission parts EP1, the plurality of second emission parts EP2 and the plurality of third emission parts EP3 of the plurality of subpixels SP may be disposed above the first gate driving unit 124, and at least one of the plurality of first emission parts EP1, the plurality of second emission parts EP2 and the plurality of third emission parts EP3 of the plurality of subpixels SP may be disposed above the second gate driving unit 126.

For example, the plurality of first emission parts EP1, the plurality of second emission parts EP2 and the plurality of third emission parts EP3 of the left half portion of one horizontal pixel line may be arranged by being shifted by different shift values along a left direction from the regions directly above the plurality of first circuit parts CP1, the plurality of second circuit parts CP2 and the plurality of third circuit parts CP3 connected thereto. The plurality of first emission parts EP1, the plurality of second emission parts EP2 and the plurality of third emission parts EP3 of the right half portion of one horizontal pixel line may be arranged by being shifted by different shift values along a right direction from the regions directly above the plurality of first circuit parts CP1, the plurality of second circuit parts CP2 and the plurality of third circuit parts CP3 connected thereto.

The shift values of the plurality of first emission parts EP1, the plurality of second emission parts EP2 and the plurality of third emission parts EP3 may gradually increase from the central line of one horizontal pixel line to the left and right end lines.

The plurality of first circuit parts CP1, the plurality of second circuit parts CP2 and the plurality of third circuit parts CP3 and the plurality of first emission parts EP1, the plurality of second emission parts EP2 and the plurality of third parts EP3 may have the same number as each other to have 1:1 correspondence. The plurality of first circuit parts CP1, the plurality of second circuit parts CP2 and the plurality of third circuit parts CP3 are disposed in the central portion CA of the display area DA, and the plurality of first emission parts EP1, the plurality of second emission parts EP2 and the plurality of third parts EP3 are disposed in the central portion CA and the edge portions EA of the display area DA. As a result, an overall width of the first, second and third circuit parts CP1, CP2 and CP3 is smaller than an overall width of the first, second and third emission parts EP1, EP2 and EP3.

In the display device 110 according to an implementation of the present disclosure, the first and second gate driving units 124 and 126 are disposed as a lower layer in the edge portions EA of the display area DA, and the first, second and third circuit parts CP1, CP2 and CP3 of the plurality of subpixels SP are disposed as a lower layer in the central portion CA of the display area DA. Further, the first, second and third emission parts EP1, EP2 and EP3 of the plurality of subpixels SP are disposed as an upper layer in the central portion CA and the edge portions EA of the display area DA. As a result, the display area DA increases and the non-display area NA decreases to achieve a narrow bezel.

FIG. 5 is a cross-sectional view showing a circuit part and an emission part of a display device according to an implementation of the present disclosure.

In FIG. 5, a light shielding pattern 132 is disposed in each of the emission block Be, the scan1 block Bs1, the scan2 block Bs2 and the first circuit part CP1 on a substrate 130, and a buffer layer 134 is disposed on the light shielding pattern 132 above the entire substrate 130.

The light shielding pattern 132 may block a light incident from a lower portion of the substrate 130. For example, the light shielding pattern 132 may have a single layer or a multiple layer of a metallic material such as molybdenum (Mo), aluminum (Al), chromium (Cr), gold (Au), titanium (Ti), nickel (Ni), neodymium (Nd), copper (Cu), or an alloy thereof.

The buffer layer 134 may block a moisture or an oxygen permeating from an exterior. For example, the buffer layer 134 may have a single layer or a multiple layer of an inorganic insulating material such as silicon oxide (SiO₂) or silicon nitride (SiNx).

A semiconductor layer 136 is disposed on the buffer layer 134 corresponding to the light shielding pattern 132, and a gate insulating layer 138 is disposed on the semiconductor layer 136 above the entire substrate 130.

The semiconductor layer 136 includes a channel region not doped with an impurity at a central portion thereof and source and drain regions doped with an impurity at both side portions of the channel region. For example, the semiconductor layer 136 may include a polycrystalline semiconductor material such as polycrystalline silicon or an oxide semiconductor material such as indium gallium zinc oxide (IGZO), zinc oxide (ZnO), tin oxide (SnO2), copper oxide (Cu2O), nickel oxide (NiO), indium tin zinc oxide (ITZO), or indium aluminum zinc oxide (IAZO).

For example, the gate insulating layer 138 may have a single layer or a multiple layer of an inorganic insulating material such as silicon oxide (SiO₂) or silicon nitride (SiNx).

A gate electrode 140 is disposed on the gate insulating layer 138 corresponding to the channel region of the semiconductor layer 136, a first capacitor electrode 142 separated from the gate electrode 140 is disposed on the gate insulating layer 138 of the first circuit part CP1, and a first interlayer insulating layer 144 is disposed on the gate electrode 140 and the first capacitor electrode 142 above the entire substrate 130.

The gate electrode 140 and the first capacitor electrode 142 may have the same layer and the same material as each other. For example, the gate electrode 140 and the first capacitor electrode 142 may have a single layer or a multiple layer of a metallic material such as molybdenum (Mo), aluminum (Al), chromium (Cr), gold (Au), titanium (Ti), nickel (Ni), neodymium (Nd), copper (Cu), or an alloy thereof.

For example, the first interlayer insulating layer 144 may have a single layer or a multiple layer of an inorganic insulating material such as silicon oxide (SiO₂) or silicon nitride (SiNx).

A second capacitor electrode 146 is disposed on the first interlayer insulating layer 144 corresponding to the first capacitor electrode 142, and a second interlayer insulating layer 148 is disposed on the second capacitor electrode 146 above the entire substrate 130.

For example, the second capacitor electrode 146 may have a single layer or a multiple layer of a metallic material such as molybdenum (Mo), aluminum (Al), chromium (Cr), gold (Au), titanium (Ti), nickel (Ni), neodymium (Nd), copper (Cu), or an alloy thereof.

For example, the second interlayer insulating layer 148 may have a single layer or a multiple layer of an inorganic insulating material such as silicon oxide (SiO₂) or silicon nitride (SiNx).

The first capacitor electrode 142, the first interlayer insulating layer 144 and the second capacitor electrode 146 may constitute the storage capacitor Cs.

A source electrode 150 and a drain electrode 152 spaced apart from each other are disposed on the second interlayer insulating layer 148 corresponding to the light shielding pattern 132, the low level power line 154 transmitting the low level signal Vss is disposed on the second interlayer insulating layer 148 of the low level block Bv, and a first planarizing layer 156 is disposed on the source electrode 150, the drain electrode 152 and the low level power line 154 above the entire substrate 130.

The source electrode 150 is connected to the light shielding pattern 132 through a contact hole in the second interlayer insulating layer 148, the first interlayer insulating layer 144, the gate insulating layer 138 and the buffer layer 134 and is connected to the source region of the semiconductor layer 136 through a contact hole in the second interlayer insulating layer 148, the first interlayer insulating layer 144 and the gate insulating layer 138.

The drain electrode 152 is connected to the drain region of the semiconductor layer 136 through a contact hole in the second interlayer insulating layer 148, the first interlayer insulating layer 144 and the gate insulating layer 138.

The source electrode 150 and the drain electrode 152 may have the same layer and the same material as each other. For example, the source electrode 150 and the drain electrode 152 may have a single layer or a multiple layer of a metallic material such as molybdenum (Mo), aluminum (Al), chromium (Cr), gold (Au), titanium (Ti), nickel (Ni), neodymium (Nd), copper (Cu), or an alloy thereof.

For example, the first planarizing layer 156 may have a single layer or a multiple layer of an organic insulating material such as photoacryl or benzocyclobutene (BCB).

The semiconductor layer 136, the gate electrode 140, the source electrode 150 and the drain electrode 152 of each of the emission block Be, the scan1 block Bs1 and the scan2 block Bs2 may constitute a stage transistor Ts, and the semiconductor layer 136, the gate electrode 140, the source electrode 150 and the drain electrode 152 of the first circuit part CP1 may constitute the fifth transistor T5.

The first, second, third, fourth and sixth transistors T1, T2, T3, T4 and T6 of the first circuit part CP1 and the first, second, third, fourth, fifth and sixth transistors T1, T2, T3, T4, T5 and T6 of the second and third circuit parts CP2 and CP3 may have the same structure as the fifth transistor T5 of the first circuit part CP1.

Although the stage transistor Ts is disposed in each of the emission block Be, the scan1 block Bs1 and the scan2 block Bs2 in the implementation of FIG. 5, the stage transistor Ts and a capacitor may be disposed in each of the emission block Be, the scan1 block Bs1 and the scan2 block Bs2 in another implementation.

The connecting electrode 158 is disposed on the first planarizing layer 156 corresponding to the fifth transistor T5, a first contact electrode 159 is disposed on the first planarizing layer 156 corresponding to the low level power line 154, and a second planarizing layer 160 is disposed on the connecting electrode 158 and the first contact electrode 159 above the entire substrate 130.

The connecting electrode 158 is connected to the drain electrode 152 of the fifth transistor T5 of the first circuit part CP1 through a contact hole in the first planarizing layer 156 and extends from the first circuit part CP1 to the first emission part EP1.

The first contact electrode 159 is connected to the low level power line 154 of the low level block Bv through a contact hole in the first planarizing layer 156.

The connecting electrodes 158 of the second and third circuit parts CP2 and CP3 may be connected to the drain electrodes 152 of the fifth transistors T5 of the second and third circuit parts CP2 and CP3, respectively, through contact holes in the first planarizing layer 156 and may extend from the second and third circuit parts CP2 and CP3 to the second and third emission parts EP2 and EP3.

For example, the connecting electrode 158 and the first contact electrode 159 may have the same layer and the same material as each other. The connecting electrode 158 and the first contact electrode 159 may have a single layer or a multiple layer of a metallic material such as molybdenum (Mo), aluminum (Al), chromium (Cr), gold (Au), titanium (Ti), nickel (Ni), neodymium (Nd), copper (Cu), or an alloy thereof.

For example, the second planarizing layer 160 may have a single layer or a multiple layer of an organic insulating material such as photoacryl or benzocyclobutene (BCB).

A first electrode 162 is disposed in each of the first, second and third emission parts EP1, EP2 and EP3 on the second planarizing layer 160, a second contact electrode 163 is disposed in the low level block Bv on the second planarizing layer 160, and a bank layer 164 is disposed on the first electrode 162 and the second contact electrode 163.

The first electrode 162 of the first emission part EP1 is connected to the connecting electrode 158 of the first circuit part CP1 through a contact hole in the second planarizing layer 160.

The second contact electrode 163 of the low level block Bv is connected to the first contact electrode 159 through a contact hole in the second planarizing layer 160, and is thus connected to the low level power line 154 of the low level block Bv.

The first electrodes 162 of the second and third emission parts EP2 and EP3 may be connected to the connecting electrodes 158 of the second and third circuit parts CP2 and CP3, respectively, through contact holes in the second planarizing layer 160.

For example, the first electrode 162 and the second contact electrode 163 may have the same layer and the same material as each other. The first electrode 162 and the second contact electrode 163 may have a single layer or a multiple layer of a transparent conductive material such as indium tin oxide (ITO) or indium zinc oxide (IZO) or an opaque metallic material such as aluminum (Al), silver (Ag), copper (Cu), lead (Pb), molybdenum (Mo), titanium (Ti), or an alloy thereof.

The first electrode 162 may be an anode.

The bank layer 164 covers an edge portion of the first electrode 162 and the second contact electrode 163 and has an opening exposing a central portion of the first electrode 162 and the second contact electrode 163.

For example, the bank layer 164 may have a single layer or a multiple layer of an organic insulating material such as photoacryl or benzocyclobutene (BCB).

An emitting layer 166 is disposed on the first electrode 162 exposed through the opening of the bank layer 164, and a second electrode 168 is disposed on the emitting layer 166 and the second contact electrode 163 exposed through the opening of the bank layer 164 above the entire substrate 130.

The second electrode 168 is connected to the second contact electrode 163 through the opening of the bank layer 164.

For example, the emitting layer 166 may include a hole assisting layer such as a hole injecting layer or a hole transporting layer, an emitting material layer and an electron assisting layer such as an electron transporting layer or an electron injecting layer.

For example, the second electrode 168 may be a cathode and may have a single layer or a multiple layer of a transparent conductive material such as indium tin oxide (ITO) or indium zinc oxide (IZO) or a half-transmissive or opaque metallic material such as aluminum (Al), silver (Ag), copper (Cu), lead (Pb), magnesium (Mg), molybdenum (Mo), titanium (Ti), or an alloy thereof.

The first electrode 162, the emitting layer 166 and the second electrode 168 of each of the first, second and third emission parts EP1, EP2 and EP3 may constitute the light emitting diode De.

An encapsulating layer 170 for preventing a permeation of an oxygen or a moisture is disposed on the second electrode 168 above the entire substrate 130. The encapsulating layer 170 may have a first encapsulating layer of an inorganic material, a second encapsulating layer of an organic material and a third encapsulating layer of an inorganic material sequentially on the second electrode 168.

For example, the first encapsulating layer and the third encapsulating layer may have a single layer or a multiple layer of an inorganic insulating material such as silicon oxide (SiO₂) or silicon nitride (SiNx), and the second encapsulating layer may include an organic insulating material such as acryl resin, epoxy resin, phenolic resin, polyamide resin, or polyimide resin.

In the display device 110, the fifth transistors T5 of the first, second and third circuit parts CP1, CP2 and CP3 of the central portion CA of the display area DA are connected to the light emitting diodes De of the first, second and third emission parts EP1, EP2 and EP3, respectively, of the edge portions of the display area DA through the connecting electrode 158.

Although the first, second and third emission parts EP1, EP2 and EP3 are disposed in the emission block Be, the scan1 block Bs1 and the scan2 block Bs2 of the edge portions EA of the display area DA in the implementation of FIG. 5, the first, second and third emission parts EP1, EP2 and EP3 may be disposed in the scan1 block Bs1 and the scan2 block Bs2 of the edge portions EA of the display area DA and may not be disposed in the emission block Be of the edge portion EA of the display area DA in another implementation. Alternatively, the first, second and third emission parts EP1, EP2 and EP3 may be disposed in the scan2 block Bs2 of the edge portions EA of the display area DA and may not be disposed in the emission block Be and the scan1 block Bs1 of the edge portion EA of the display area DA in another implementation.

Consequently, in the display device 110 according to an implementation of the present disclosure, the first and second gate driving units 124 and 126 are disposed as a lower layer in the edge portions EA of the display area DA, and the first, second and third circuit parts CP1, CP2 and CP3 of the plurality of subpixels SP are disposed as a lower layer in the central portion CA of the display area DA. The first, second and third emission parts EP1, EP2 and EP3 of the plurality of subpixels SP are disposed as an upper layer in the central portion CA and the edge portions EA of the display area DA, and the first, second and third circuit parts CP1, CP2 and CP3 of the central portion CA of the display area DA are connected to the first, second and third emission parts EP1, EP2 and EP3 of the edge portions EA of the display area DA through the connecting electrode 158.

The first and second gate driving units 124 and 126 are disposed in the edge portions EA of the display area DA, and the first, second and third circuit parts CP1, CP2 and CP3 are disposed in the central portion CA of the display area DA. Further, the first, second and third emission parts EP1, EP2 and EP3 are disposed in the central portion CA and the edge portions EA of the display area DA. As a result, the display area DA increases and the non-display area NA decreases to achieve a narrow bezel.

It will be apparent to those skilled in the art that various modifications and variation may be made in the present disclosure without departing from the scope of the disclosure. Thus, it is intended that the present disclosure cover the modifications and variations of this disclosure provided they come within the scope of the appended claims and their equivalents.

What is claimed is:

1. A display device, comprising:
a display panel having a display area and a non-display area at a periphery of the display area;
first and second gate driving units in edge portions of the display area;
a plurality of circuit parts in a central portion of the display area between the edge portions and connected to the first and second gate driving units; and
a plurality of emission parts above the first and second gate driving units and the plurality of circuit parts and connected to the plurality of circuit parts.

2. The display device of claim 1, wherein the plurality of emission parts are arranged by being shifted by different shift values along each of left and right directions from a region directly above the plurality of circuit parts connected thereto.

3. The display device of claim 1, wherein
the plurality of emission parts are arranged by being shifted by different shift values along each of left and right directions from a region directly above the plurality of circuit parts connected thereto, and the shift values gradually increase from a central line of the display area to left and right end lines of the display area; and/or
the plurality of circuit parts and the plurality of emission parts have the same number as each other.

4. The display device of claim 1, wherein the plurality of circuit parts include first, second and third circuit parts,
wherein the plurality of emission parts include first, second and third emission parts,
wherein the first, second and third circuit parts are sequentially and repeatedly disposed in the central portion of the display area, and
wherein the first, second and third emission parts are sequentially and repeatedly disposed throughout an entirety of the display area.

5. The display device of claim 4, wherein an overall width of the first, second and third circuit parts is smaller than an overall width of the first, second and third emission parts.

6. The display device of claim 4, wherein the first, second and third circuit parts of the central portion of the display area are connected to the first, second and third emission parts, respectively, of the entirety of the display area through a connecting electrode.

7. The display device of claim 4, wherein each of the first, second and third circuit parts includes at least one transistor,
wherein each of the first, second and third emission parts includes a light emitting diode, and
wherein the at least one transistor is connected to the light emitting diode through a connecting electrode.

8. The display device of claim 7, wherein a first planarizing layer is disposed on the at least one transistor,
wherein the connecting electrode is connected to the at least one transistor through a contact hole in the first planarizing layer,
wherein a second planarizing layer is disposed on the connecting electrode,
wherein the light emitting diode is disposed on the second planarizing layer, and
wherein the light emitting diode is connected to the connecting electrode through a contact hole in the second planarizing layer.

9. The display device of claim 1, wherein the first and second gate driving units generate a gate signal using a gate control signal and supply the gate signal to the plurality of circuit parts.

10. The display device of claim 9, further comprising:
a data driving unit that generates a data signal using an image data and a data control signal and supplying the data signal to the plurality of circuit parts; and
a timing controlling unit that generates the image data, the data control signal and the gate control signal using an image signal and a timing signal, the timing controlling unit transmitting the image data and the data control signal to the data driving unit and transmitting the gate control signal to the first and second gate driving units.
